(19) United States
(12) Patent Application Publication
(10) Pub. No.: US 2010/0252094 A1
(43) Pub. Date: Oct. 7, 2010

(54) High-Efficiency Solar Cell and Method of Manufacturing the Same

(75) Inventors: Hyun Soo Kim, Daejeon (KR); Won Seok Han, Daejeon (KR); Byung Seok Choi, Daejeon (KR); Dae Kon Oh, Daejeon (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon (KR)

(21) Appl. No.: 12/676,734

(22) PCT Filed: Jul. 31, 2008
(86) PCT No.: PCT/KR2008/004463

§ 371 Date: Mar. 5, 2010

(30) Foreign Application Priority Data
Oct. 5, 2007 (KR) 10-2007-0100597

(51) Int. Cl. H01L 31/00; H01L 31/18

(52) U.S. Cl. 136/252; 438/72; 257/E31.127

(57) ABSTRACT

Provided are a high-efficiency solar cell, which converts light energy of incident light into electrical energy, and a method of manufacturing the same. An upper ohmic layer is formed at a predetermined tilt angle less than 45° and an ohmic electrode is deposited on the upper ohmic layer so as to reduce shadow loss due to the ohmic electrode and lessen contact resistance.

### TECHNICAL FIELD

The present invention relates to a high-efficiency solar cell and a method of manufacturing the same, and more particularly, to a high-efficiency solar cell and a method of manufacturing the same, wherein an upper ohmic layer of a semiconductor solar cell is formed at a tilt angle of less than 45° and an ohmic electrode is deposited on the upper ohmic layer so as to lessen shadow loss due to the ohmic electrode and to reduce contact resistance.

This work was supported by the IT R&D program of MIC/IITA. [2006-S-006-02, Component modules for ubiquitous terminals].

### BACKGROUND ART

A solar cell is a semiconductor device that converts solar energy into electrical energy and has a p-n junction structure. An n-type semiconductor region contains a large number of electrons for majority carriers, while a p-type semiconductor region contains a large number of holes for majority carriers. Thus, when a p-n junction is formed, inter-diffusion of carriers occurs between the n- and p-type semiconductor regions due to a concentration gradient. In this case, space charges are generated to cause built-in potentials. When diffusion components dependent on carriers become equivalent to drift components dependent on the built-in potentials, the solar cell enters a parallel state. Also, when photons having energy higher than the bandgap of a p-n junction diode are incident to the solar cell, electrons receive light energy and are excited from a valence band to a conduction band to thereby generate electron-hole pairs. Thus, both electrodes of the p-n junction diode are connected to an external circuit and transmit electromotive force (EMF) to the external circuit so that the solar cell can perform its proper functions.

Conventional solar cells employ p-n homojunctions formed of single-crystalline silicon (Si). This is because although the solar cells have slightly low photoelectric conversion efficiency, they are less expensive.

In comparison with a III-V group GaAs-based single-crystalline solar cell having a direct bandgap, a Si solar cell having an indirect bandgap has lower photoelectric conversion efficiency, but the Si solar cell is much less expensive and more widely used.

However, in recent years, much research has been done into solar cells with concentrators for focusing light using lenses, and as a result, a percentage taken by a solar cell in the total price of the solar cell system is decreasing greatly. Also, although the photoelectric conversion efficiency of Si solar cells has not greatly been developed since the nineties, the photoelectric conversion efficiency of III-V Group GaAs-based single-crystalline solar cells has been gradually increasing by about 1% every year. Thus, the III-V Group GaAs-based single-crystalline solar cells exhibit about twice the photoelectric conversion efficiency of the Si solar cells. And while Si solar cells with concentrators focus light 20 times as efficiently, III-V Group GaAs-based single-crystalline solar cells with concentrators focus light 500 times as efficiently. Thus, it is expected that the III-V Group GaAs-based single-crystalline solar cells with concentrators will lead the Si solar cells with concentrators in terms of price competitiveness.

FIGS. 1A and 1B are a cross-sectional view and a top view of a conventional III-V Group GaAs-based single-crystalline solar cell, respectively.

Referring to FIG. 1A, the III-V Group GaAs-based single-crystalline solar cell includes a p-type GaAs substrate 110, a back surface field (BSF) layer 120, a light absorption layer 130, a window layer 140, and an n⁺-type ohmic layer 150, which are stacked sequentially, and ohmic electrodes 160 and 170 are formed on and under the tandem structure, respectively. The light absorption layer 130 is used to convert light energy into electrical energy, and the n⁺-type ohmic layer 150 is used for an ohmic junction. Also, an anti-reflection (AR) layer 180 is formed on the window layer 140 in order to reduce reflection loss.

The BSF layer 120 is heavily doped so as to reduce a recombination rate at an interface between the BSF layer 120 and the lightly doped light absorption layer 130. Also, the window layer 140 functions to reduce a recombination rate on the surface of the window layer 140 to allow most of incident light to be absorbed by the light absorption layer 130. Furthermore, the window layer 140 is used to minimize the reflection rate of incident light along with the AR layer 180.

The upper ohmic electrode 160 and the lower ohmic electrode 170 are used to transmit EMF generated by both electrodes of a p-n junction diode to an external circuit. As shown in FIG. 1B, the upper ohmic electrode 160 includes a grid line 161, a bus line 162, and a metal pad 163.

Since GaAs has a high refractive index of about 4, the AR layer 180 is used to lessen reflection loss that occurs due to a difference in refractive index between air and GaAs. In general, the AR layer 180 is a single dielectric thin layer, such as a SiN_{X} layer, a SiO₂ layer, or an indium tin oxide (ITO) layer, or a multiple dielectric layer, such as a MgF₂/ZnS layer or a Ta₂O₅/SiO₂ layer.

However, in the above-described solar cell, since the upper ohmic electrode 160 is vertically etched as shown in FIG. 1A, shadow loss occurs due to light incident to the upper ohmic electrode 160.

In general, when the n⁺-type ohmic layer 150 is formed of Si, the upper ohmic electrode 160 is formed of Al or Ag and when the n⁺-type ohmic layer 150 is formed of GaAs, the upper ohmic electrode 160 is formed of AuGe/Ni/Au or Au. Owing to interfacial characteristics between the n⁺-type ohmic layer 150 and the upper ohmic electrode 160, incident light is reflected and causes shadow loss, thereby lowering photoelectric conversion efficiency.

In order to improve the photoelectric conversion efficiency of a solar cell, an upper ohmic electrode may be formed of a transparent material, such as SnO₂, In₂O₃, or TiO₂. However, the transparent upper ohmic electrode has poorer characteristics than other ordinary metal electrodes.

Accordingly, in order to reduce shadow loss of the upper ohmic electrode, it is important to lessen an area occupied by a grid line, bus line, and metal pad. However, as the width of the upper ohmic electrode decreases, the contact resistance of the upper ohmic electrode increases, thereby deteriorating photoelectric conversion efficiency.

Furthermore, when a spacing between grid lines (or a grid spacing) is increased, shadow loss may decrease, but electrons (or holes) caused by solar light are recombined and lost. Thus, shadow loss due to the grid spacing is traded off with shadow loss due to recombination of carriers. Therefore, it is very complicated to optimize the grid width and grid spacing while considering contact resistance, shadow loss, and recombination of carriers.

In another approach, an upper ohmic electrode 260 having a curved surface may be formed as shown in FIG. 2 to lessen shadow loss.

FIG. 2 is a cross-sectional view of a conventional upper ohmic electrode having a curved surface.

Referring to FIG. 2, an n-type Si ohmic layer 220 is formed on a p-type Si substrate 210, and a concave curved surface is etched in the p-type Si substrate 210. The upper ohmic electrode 260 is formed on the etched surface, and a lower ohmic electrode 240 is formed under the p-type Si substrate 210. Also, an AR layer 250 is deposited on the n-type Si ohmic layer 220 to lessen reflection loss of incident solar light.

Compared to the upper ohmic electrode 160 shown in FIG. 1, the curved-surface upper ohmic electrode 260 can reduce contact loss caused by an increase in contact area. However, shadow loss still occurs due to the upper ohmic electrode 260.

A third method of lessening shadow loss of an upper ohmic electrode is illustrated in FIG. 3.

FIG. 3 is a cross-sectional view of a conventional ohmic electrode using a via hole.

Referring to FIG. 3, both an upper ohmic electrode 360 and a lower ohmic electrode 370 are formed on a bottom surface of a substrate 320 and connected by a via hole 350, so that shadow loss caused by the upper ohmic electrode 360 can be reduced.

However, since a typical substrate has a thickness of about 200 to 800 μm, it is difficult to dry or wet etch the thick substrate to form a via hole. Also, unlike when a p-n homojunction formed of a single material is formed as shown in FIG. 3, a III-V Group GaAs-based solar cell having a tandem structure must adopt a heterojunction formed of different materials, making it name difficult to form the via hole.

### DISCLOSURE OF INVENTION

### Technical Problem

The present invention is directed to a high-efficiency solar cell, which lessens shadow loss caused by an upper ohmic electrode so as to improve photoelectric conversion efficiency, and a method of manufacturing the same.

### Technical Solution

One aspect of the present invention provides a high-efficiency solar cell for converting light energy of incident light into electrical energy, the solar cell comprising an upper ohmic layer and an upper ohmic electrode of which lateral surfaces have a predetermined tilt angle to allow the incident light to be incident into the solar cell.

Another aspect of the present invention provides a method of manufacturing a high-efficiency solar cell. The method comprising: forming an etch mask using a photolithography process on a substrate including a back surface field (BSF) layer, a light absorption layer, a window layer, and an upper ohmic layer that are formed sequentially; etching a lateral surface of the upper ohmic layer to have a predetermined tilt angle; and forming an upper ohmic electrode using a metallization process on the upper ohmic layer having the lateral surface with the predetermined tilt angle.

Still another aspect of the present invention provides a method of manufacturing a high-efficiency solar cell. The method comprising: forming a growth prevention mask using a photolithography process on a substrate on which a back surface field (BSF) layer, a light absorption layer, and a window layer are formed sequentially; selectively growing an upper ohmic layer on a portion of the window layer using the growth prevention mask such that the upper ohmic layer has a lateral surface with a predetermined tilt angle; and forming an upper ohmic electrode using a metallization process on the upper ohmic layer having the lateral surface with the predetermined tilt angle.

The predetermined tilt angle may be less than 45°, so that incident light incident to the lateral surface of the upper ohmic electrode is reflected at a reflection angle greater than the predetermined tilt angle and incident to the solar cell.

### Advantageous Effects

According to the present invention as described above, an upper ohmic layer of a semiconductor solar cell is formed at a tilt angle less than about 45°, and an ohmic electrode is deposited on the upper ohmic layer, thereby lessening shadow loss caused by the ohmic electrode and reducing contact resistance.

Also, according to the present invention, it is possible to form an ohmic electrode with an appropriately wide ohmic contact width and a minimum grid spacing.

### BRIEF DESCRIPTION OF THE DRAWINGS

FIGS. 1A and 1B are a cross-sectional view and a top view, respectively, of a conventional III-V Group GaAs-based single-crystalline solar cell;

FIG. 2 is a cross-sectional view of a conventional curved-surface upper ohmic electrode;

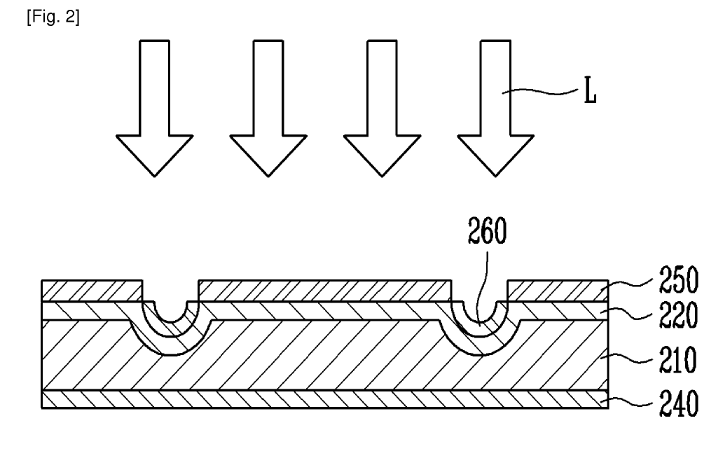

FIG. 3 is a cross-sectional view of a conventional ohmic electrode using a via hole;

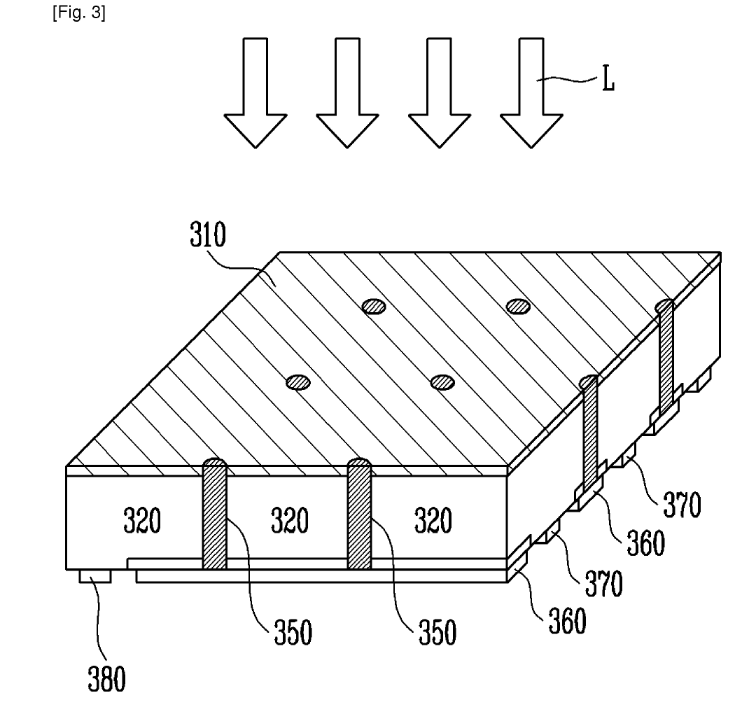

FIG. 4 is a cross-sectional view of a high-efficiency solar cell according to an exemplary embodiment of the present invention;

FIG. 5A is a cross-sectional view of a high-efficiency solar cell according to another exemplary embodiment of the present invention, and FIG. 5B is a magnified cross-sectional view of an upper ohmic layer and an upper ohmic electrode of FIG. 5A;

FIG. 6A is a graph showing the minimum grid spacing and ohmic contact width relative to a mesa angle in a solar cell according to an exemplary embodiment of the present invention, and FIG. 6B is a graph showing the minimum grid spacing and ohmic contact width relative to the thickness of an upper ohmic layer according to an exemplary embodiment of the present invention;

FIGS. 7A through 7D are diagrams for explaining a process of forming an inclined upper ohmic layer using a selective wet etchant according to an exemplary embodiment of the present invention;

FIG. 8 is a diagram for explaining a process of forming an upper ohmic layer with an inclined lateral surface using a reactive dry etching process according to an exemplary embodiment of the present invention;

FIGS. 9A through 9C are diagrams for explaining a process of forming an inclined upper ohmic layer using a selective area growth process according to an exemplary embodiment of the present invention; and

FIG. 10 is a diagram for explaining a method of varying a reflection angle by shifting the direction of a grid line with respect to a substrate direction in an upper ohmic electrode according to the present invention.

### MODE FOR THE INVENTION

Hereinafter, a high-efficiency solar cell and a method of manufacturing the same according to the present invention will be described name fully with reference to the accompanying drawings, in which exemplary embodiments of the invention are shown.

### Embodiment 1

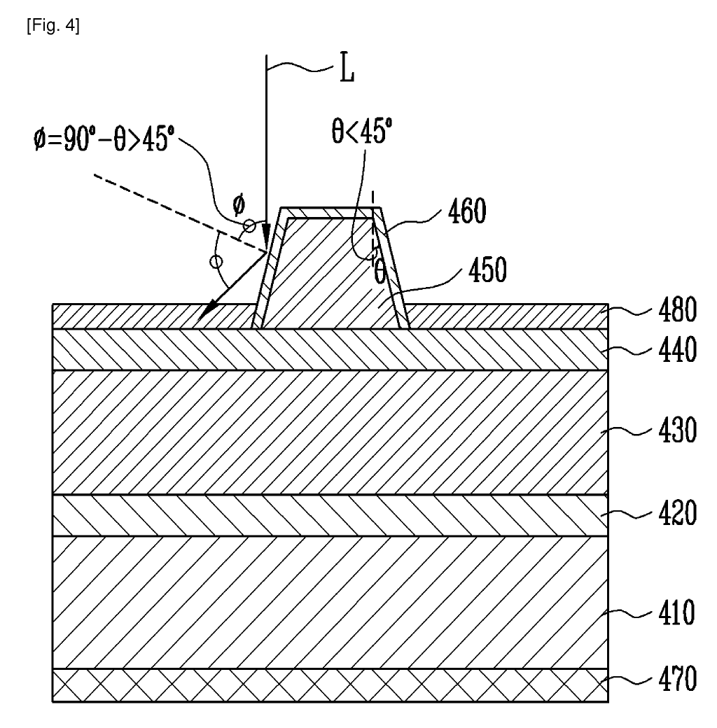

FIG. 4 is a cross-sectional view of a high-efficiency solar cell according to an exemplary embodiment of the present invention.

Referring to FIG. 4, according to the present embodiment, when an upper ohmic layer 450 of the solar cell is formed, an inclined lateral surface is formed using a dry or wet etching process. Thereafter, an upper ohmic electrode 460 is formed on the inclined lateral surface.

In this case, the inclined lateral surface is formed at a tilt angle 0 less than 45°, so that light is incident to the inclined lateral surface at an incidence angle φ greater than 45°.

As shown in FIG. 4, when the upper ohmic electrode 460 is formed on the mesa-type upper ohmic layer 450 with a tilt angle θ less than 45°, the upper ohmic electrode 460 also has a mesa structure with a tilt angle θ less than 45°.

Accordingly, incident light L is incident to the lateral surface of the upper ohmic electrode 460 and reflected by the lateral surface of the upper ohmic electrode 460 at a reflection angle greater than 45°. Thus, the incident light L is not scattered elsewhere but incident to the solar cell via an anti-reflection (AR) layer 480, so that the ohmic electrode 460 does not cause shadow loss.

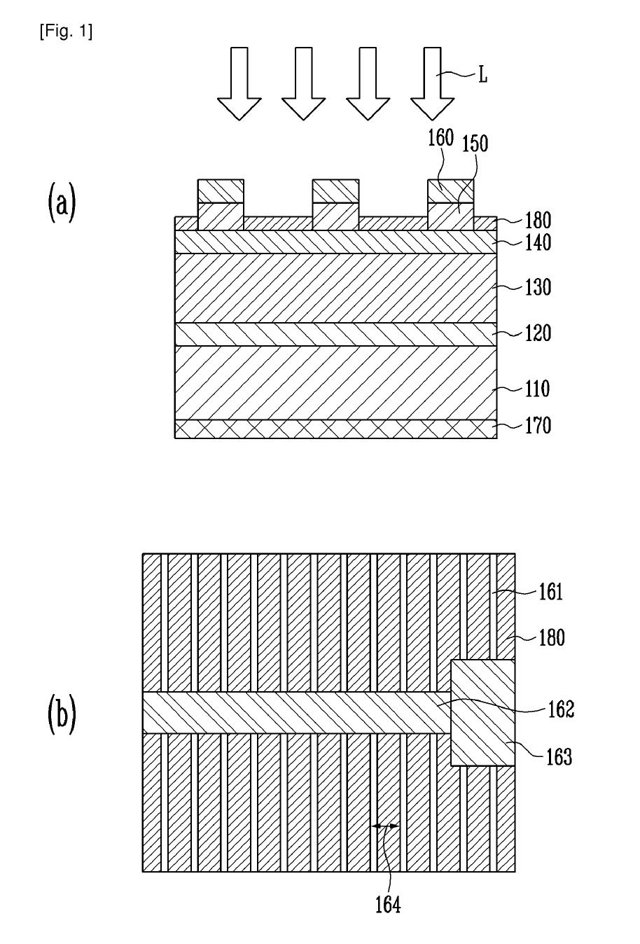

Also, the mesa-type ohmic electrode 460 according to the present embodiment has a greater ohmic contact width between the ohmic electrode 460 and the ohmic layer 450 than the square ohmic electrode shown in FIG. 1A. As a result, a contact resistance between the ohmic electrode 460 and the ohmic layer 450 decreases, and the solar cell according to the present embodiment can have higher photoelectric current efficiency than the conventional solar cell shown in FIG. 1A.

Meanwhile, although the present embodiment exemplarily describes a III-V Group GaAs-based single-crystalline solar cell, the present invention can be applied to all kinds of solar cells, such as single-crystalline Si solar cells, poly-crystalline Si solar cells, amorphous Si solar cells, Cu—In—Ge—Sn (CIGS) solar cells, dye-sensitized solar cells (DSSCs), etc.

### Embodiment 2

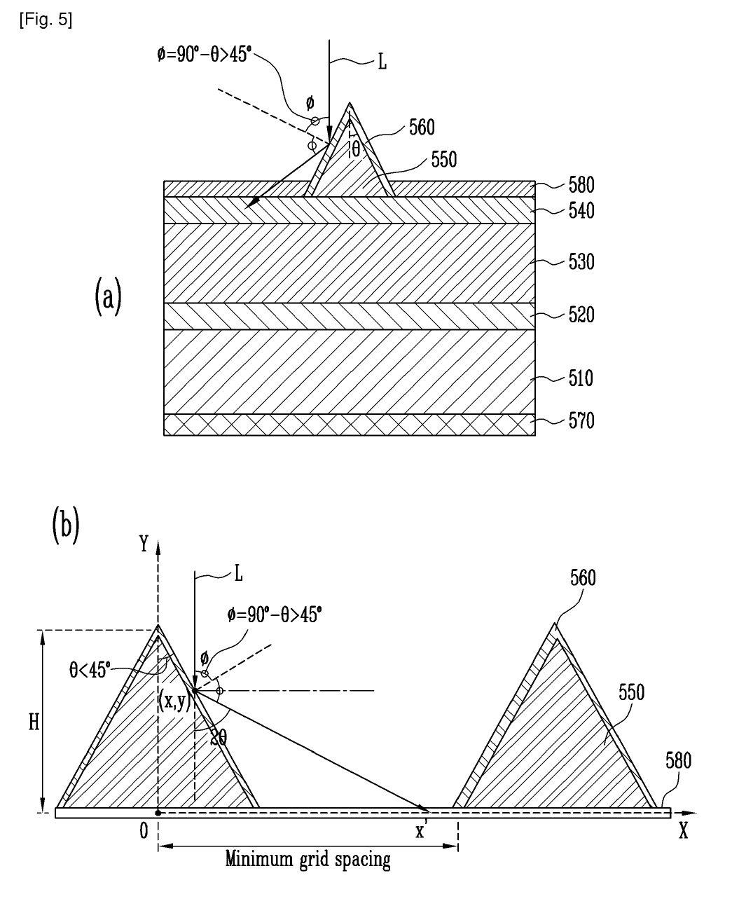

FIG. 5A is a cross-sectional view of a high-efficiency solar cell according to another exemplary embodiment of the present invention, and FIG. 5B is a magnified cross-sectional view of an upper ohmic layer and an upper ohmic electrode shown in FIG. 5A.

Referring to FIG. 5A, an upper ohmic layer 550 has no flattened top surface, as did the solar cell shown in FIG. 4, but only inclined lateral surfaces.

In other words, the upper ohmic layer 550 has a triangular shape, and an upper ohmic electrode 560 formed on the upper ohmic layer 550 also has a triangular shape.

As compared with the solar cell shown in FIG. 4, the solar cell according to the present embodiment can eliminate shadow loss more effectively and has a greater ohmic contact width so as to further reduce contact resistance. These effects will be described in further detail below.

Referring to FIG. 5B, when incident light L is incident to the lateral surface of the upper ohmic electrode 560 with a tilt angle θ, the reflection angle φ of light reflected by the inclined lateral surface of the upper ohmic electrode 560 becomes 90°-θ.

That is, when the tilt angle θ is less than 45°, the reflection angle φ becomes greater than 45°, so that the reflected light is not scattered externally but incident to the solar cell. In this case, it is necessary to keep a minimum grid spacing so as not to re-reflect the reflected light by an adjacent lateral surface of the upper ohmic electrode 560.

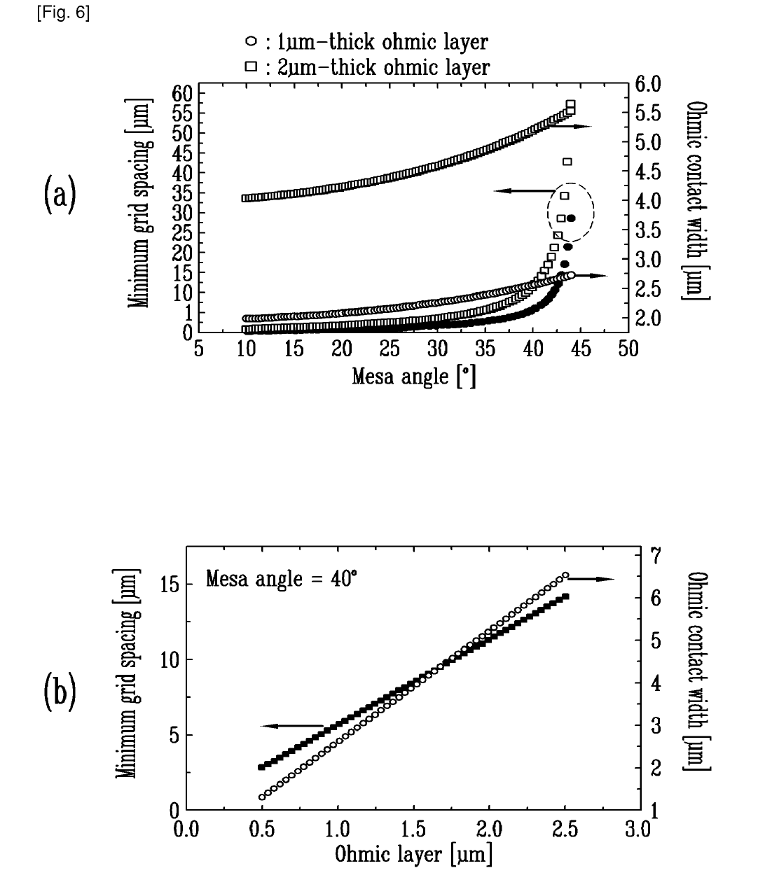

FIG. 6A is a graph showing the minimum grid spacing and ohmic contact width relative to a mesa angle in a solar cell according to an exemplary embodiment of the present invention, and FIG. 6B is a graph showing the minimum grid spacing and ohmic contact width relative to the thickness of an upper ohmic layer according to an exemplary embodiment of the present invention.

Referring to FIG. 6A, as the mesa angle (or a tilt angle) increases, the ohmic contact width gradually increases, but the minimum grid spacing sharply increases at a mesa angle of 42° or more.

That is, an ohmic electrode of the solar cell should be designed to maximize ohmic contact width and minimize minimum grid spacing. Referring to FIG. 6A, it can be seen that the mesa angles ranging from about 30° to 42° are best suited to appropriately increase ohmic contact width and reduce minimum grid spacing.

FIG. 6B is a graph of a minimum grid spacing and an ohmic contact width relative to the thickness of an upper ohmic layer when the mesa angle is fixed at 40°. Referring to FIG. 6B, as the thickness of the upper ohmic layer increases, the minimum grid spacing increases, and the ohmic contact width also increases linearly.

A conventional ohmic layer of a III-V Group GaAs-based solar cell is formed to a thickness of approximately 0.1 to 0.5 μm, while a solar cell according to the present invention adopts an ohmic layer with a thickness of 0.5 μm or name.

Hereinafter, a method of forming an inclined upper ohmic layer according to the present invention will be described in further detail.

The ohmic upper layers with the inclined lateral surfaces shown in FIGS. 4 and 5A may be formed using a selective etching process or a selective area growth process. The selective etching process and the selective area growth process will now both be described in further detail.

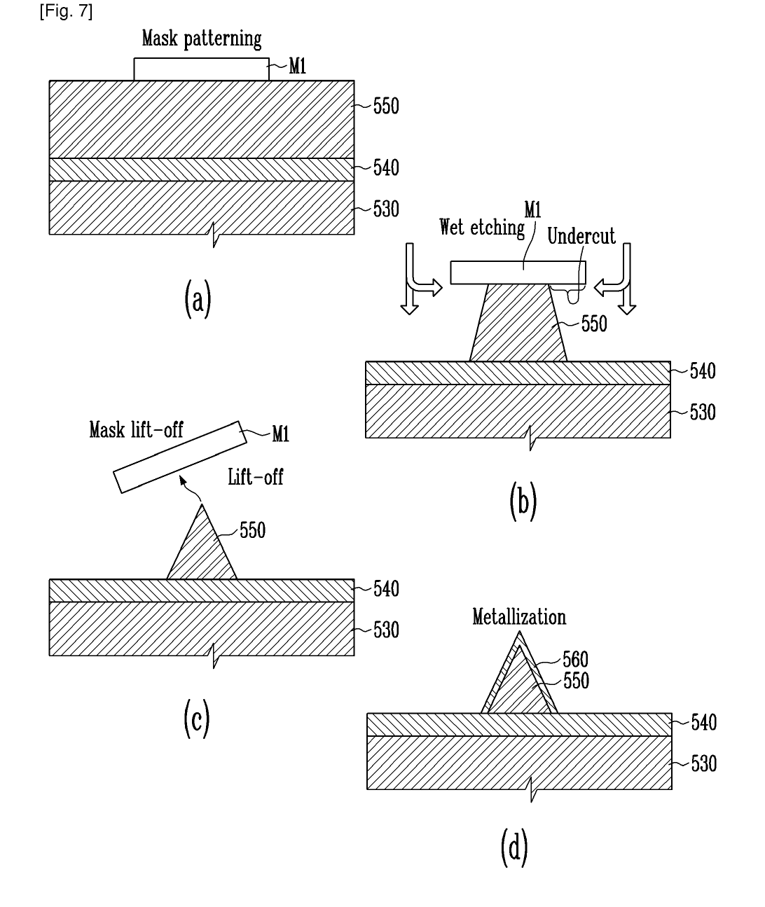

FIGS. 7A through 7D are diagrams for explaining a process of forming an inclined upper ohmic layer using a selective wet etchant according to an exemplary embodiment of the present invention.

Referring to FIG. 7A, an etch mask M1 is formed on an ohmic layer 550 using a photolithography process, and then the ohmic layer 550 is wet etched as shown in FIG. 7B.

In this case, the ohmic layer 550 is not only etched in a vertical direction due to a wet etchant, but also etched in a horizontal direction to form an undercut, thereby resulting in the inclined ohmic layer 550.

The etch mask M1 may be a hard mask or a soft mask. The hard mask may be a SiN_{X} mask, a SiO₂ mask, or a metal mask, and the soft mask may be photoresist (PR). However, the soft mask is more appropriate than the hard mask in facilitating the formation of the undercut.

Referring to FIG. 7C, when the wet etching process is continuously performed, the etch mask M1 is lifted off due to the undercut, thereby completing the inclined ohmic layer 550.

Referring to FIG. 7D, an upper ohmic electrode 560 is formed using a metallization process.

In addition to the wet etching process, the upper ohmic layer 550 may be etched into an inclined shape using a reactive dry etching process as follows.

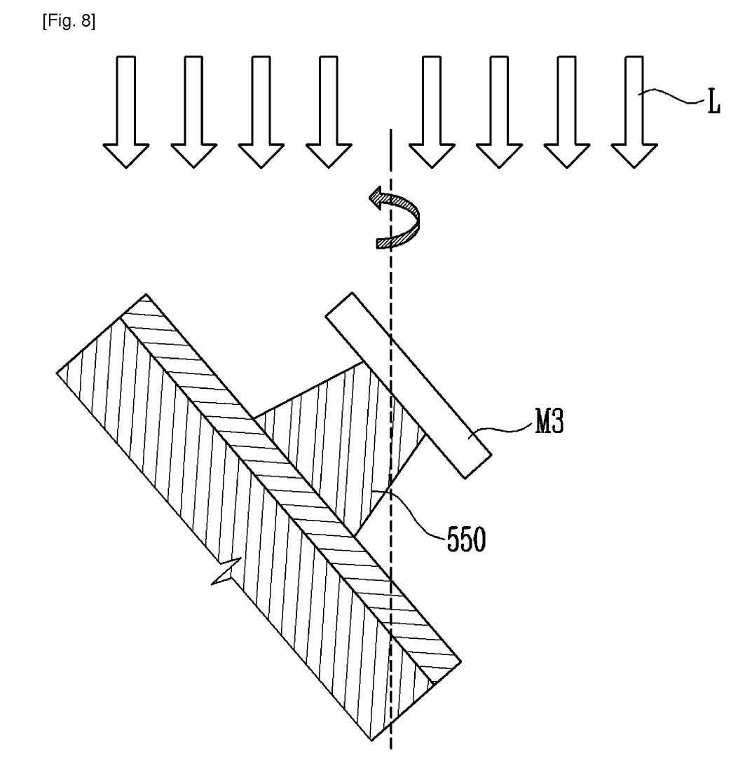

FIG. 8 is a diagram for explaining a process of forming the upper ohmic layer 550 with an inclined lateral surface using a reactive dry etching process according to an exemplary embodiment of the present invention. Referring to FIG. 8, a sample is arranged aslant at a desired angle in a reactor and processed using a reactive dry etching process, thereby forming the upper ohmic layer 550 with an inclined lateral surface.

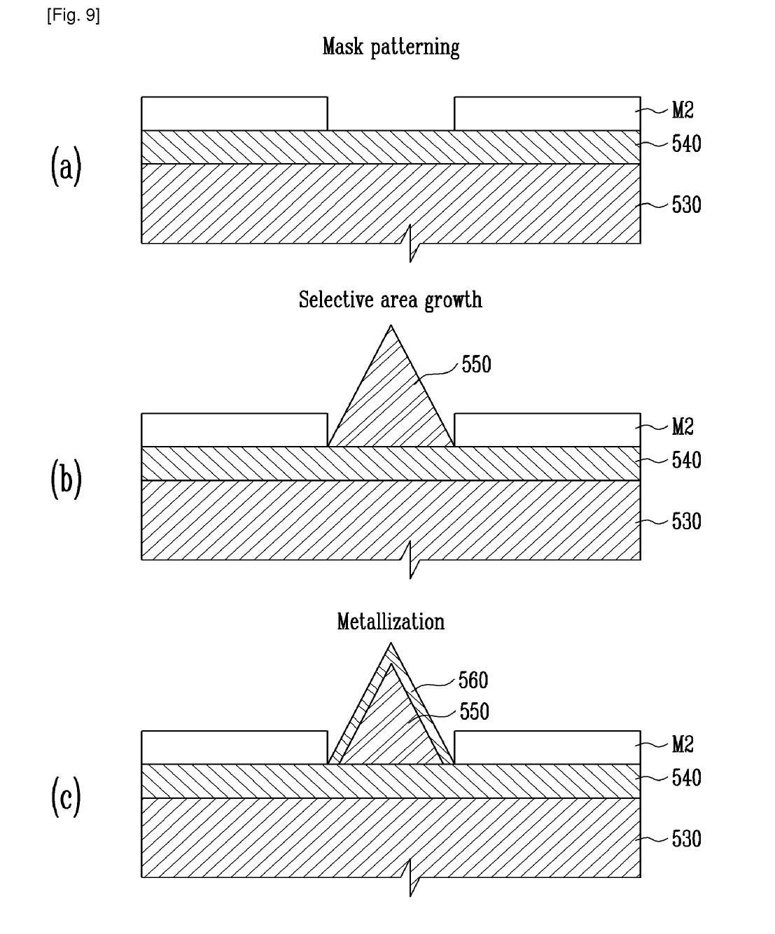

FIGS. 9A through 9C are diagrams for explaining a process of forming an inclined upper ohmic layer using a selective area growth process according to an exemplary embodiment of the present invention.

Referring to FIG. 9A, a growth prevention mask M2 is formed on a window layer 540 using a photolithography process, and then an ohmic layer 550 is grown using a selective area growth process as shown in FIG. 9B. In this case, the growth prevention mask M2 may be a dielectric layer, such as a SiN_{X} layer or a SiO₂ layer.

Referring to FIG. 9C, an upper ohmic electrode 560 is formed using a metallization process.

The growth prevention mask M2 may be formed to an appropriate thickness and used as an AR layer. In this case, after the upper ohmic electrode 560 is formed, the manufacture of the solar cell is completed without adding any subsequent process, thereby simplifying the entire process.

Meanwhile, when the inclined upper ohmic electrode 560 is formed using the above-described selective etching process or the selective area growth process, the reflection angle of incident light can be varied by shifting the direction of a grid line in the upper ohmic electrode 560, as will be described in further detail below.

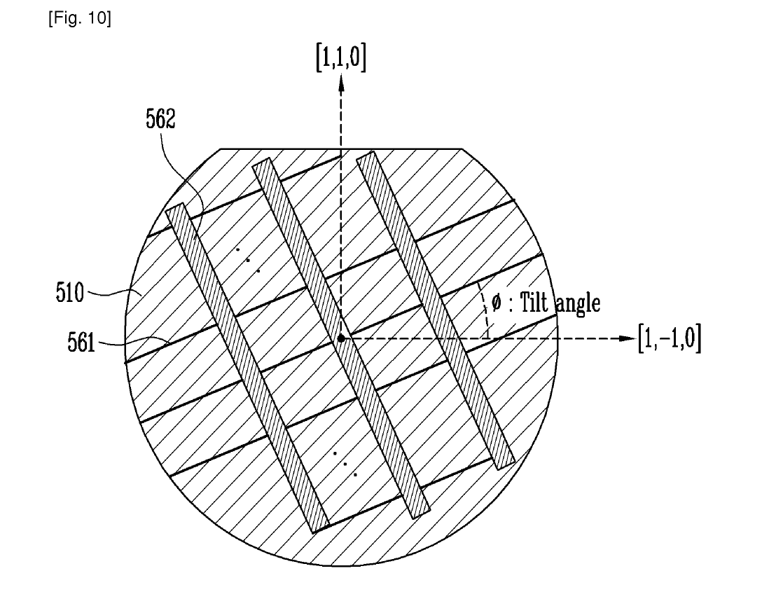

FIG. 10 is a diagram for explaining a method of varying a reflection angle by shifting the direction of a grid line with respect to a substrate direction in the upper ohmic electrode 560 according to the present invention. Referring to FIG. 10, when the grid line is tilted at a predetermined angle with respect to the substrate direction, the reflection angle of incident light can be controlled to a desired angle.

Meanwhile, in the above-described solar cell in which an upper ohmic layer and an ohmic electrode are inclined at a predetermined angle, a metal layer made of a metal which has a high reflection rate in ultraviolet (UV) and visible (V) regions (e.g. an Ag layer), may be additionally deposited on the upper ohmic electrode 560 in order to improve the reflective characteristics of metals. In this case, the ohmic electrode can have a higher reflection rate, thereby improving photoelectric conversion efficiency. Also, a bus line of the upper ohmic electrode 560 may be formed in the same manner as the grid line shown in FIG. 10 so as to further enhance the photoelectric conversion efficiency.

While the invention has been shown and described with reference to m certain exemplary embodiments thereof, it will be understood by those skilled in the art that various changes in form and details may be made therein without departing from the spirit and scope of the invention as defined by the appended claims.

1. A high-efficiency solar cell for converting light energy of incident light into electrical energy, the solar cell comprising an upper ohmic layer and an upper ohmic electrode of which lateral surfaces have a predetermined tilt angle to allow the incident light to be incident into the solar cell.

2. The solar cell according to claim 1, wherein the predetermined tilt angle is less than 45°.

3. The solar cell according to claim 1, wherein the upper ohmic electrode is disposed on the upper ohmic layer in the same shape as the upper ohmic layer.

4. The solar cell according to claim 1, wherein the incident light incident to the lateral surface of the upper ohmic electrode is reflected at a reflection angle greater than the predetermined tilt angle and incident to the solar cell.

5. The solar cell according to claim 1, wherein the lateral surface of the upper ohmic layer is etched using a selective wet etching process or a reactive dry etching process to have the predetermined tilt angle.

6. The solar cell according to claim 1, wherein the lateral surface of the upper ohmic layer is grown using a selective area growth process to have the predetermined tilt angle.

7. The solar cell according to claim 1, wherein each of the upper ohmic layer and the upper ohmic electrode has a triangular shape.

8. The solar cell according to claim 1, wherein a grid line, a bus line, and a metal pad are disposed on the upper ohmic electrode, and the grid line is formed to satisfy a minimum grid spacing such that reflected light is not reflected again by an adjacent lateral surface of the upper ohmic electrode.

9. The solar cell according to claim 1, wherein when the grid line of the upper ohmic electrode is inclined at a predetermined angle with respect to a substrate direction, the reflection angle of the upper ohmic electrode is varied according to the predetermined angle.

10. The solar cell according to claim 1, wherein when the bus line of the upper ohmic electrode is inclined at a predetermined angle with respect to a substrate direction, the reflection angle of the upper ohmic electrode is varied according to the predetermined angle.

11. The solar cell according to claim 1, wherein a metal layer having a high reflection rate in ultraviolet (UV) and visible (V) regions is deposited on the upper ohmic electrode.

12. A method of manufacturing a high-efficiency solar cell, comprising:
forming an etch mask using a photolithography process on a substrate including a back surface field (BSF) layer, a light absorption layer, a window layer, and an upper ohmic layer that are formed sequentially;
etching a lateral surface of the upper ohmic layer to have a predetermined tilt angle; and
forming an upper ohmic electrode using a metallization process on the upper ohmic layer having the lateral surface with the predetermined tilt angle.

13. The method according to claim 12, wherein the lateral surface of the upper ohmic layer is etched using a selective wet etching process or a reactive dry etching process.

14. The method according to claim 12, wherein the etch mask is a soft mask including photoresist.

15. The method according to claim 12, wherein the predetermined tilt angle is less than 45°.

16. The method according to claim 12, further comprising forming a grid line, a bus line, and a metal pad on the upper ohmic electrode,
wherein the grid line is formed to satisfy a minimum grid spacing not to re-reflect reflected light by an adjacent lateral surface of the upper ohmic layer.

17. The method according to claim 16, further comprising varying the reflection angle of the upper ohmic electrode by forming the grid line or bus line of the upper ohmic electrode at a predetermined angle to the direction of the substrate.

18. The method according to claim 12, further comprising depositing a metal layer having a high reflection rate in ultraviolet (UV) and visible (V) regions on the upper ohmic electrode.

19. A method of manufacturing a high-efficiency solar cell, comprising:
forming a growth prevention mask using a photolithography process on a substrate on which a back surface field (BSF) layer, a light absorption layer, and a window layer are formed sequentially;
selectively growing an upper ohmic layer on a portion of the window layer using the growth prevention mask such that the upper ohmic layer has a lateral surface with a predetermined tilt angle; and
forming an upper ohmic electrode using a metallization process on the upper ohmic layer having the lateral surface with the predetermined tilt angle.

20. The method according to claim 19, wherein the growth prevention mask is a dielectric layer.

21. The method according to claim 19, wherein the growth prevention mask is an anti-reflection (AR) layer.

22. The method according to claim 19, wherein the predetermined tilt angle is less than 45°.

23. The method according to claim 19, further comprising forming a grid line, a bus line, and a metal pad on the upper ohmic electrode,
wherein the grid line is formed to satisfy a minimum grid spacing not to re-reflect reflected light by an adjacent lateral surface of the upper ohmic layer.

24. The method according to claim 23, further comprising varying the reflection angle of the upper ohmic electrode by forming the grid line or bus line of the upper ohmic electrode at a predetermined angle to the direction of the substrate.

25. The method according to claim 19, further comprising depositing a metal layer having a high reflection rate in ultraviolet (UV) and visible (V) regions on the upper ohmic electrode.
